(19) United States
(12) Patent Application Publication
(10) Pub. No.: US 2008/0068052 A1
(43) Pub. Date: Mar. 20, 2008

(54) FREQUENCY DOUBLER USING DUAL GILBERT MIXERS

(75) Inventors: Tung-Meng Tsai, Hsin Chu (TW); Boson Lin, Hsin Chu (TW); Wen-Yu Huang, Hsin Chu (TW); Son-Fu Yeh, Hsin Chu (TW); Chia-Meng Lee, Hsin Chu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: EE Solutions, Inc, Hsin Chu (TW)

(21) Appl. No.: 11/533,373

(22) Filed: Sep. 20, 2006

(51) Int. Cl. H03B 19/00

(52) U.S. Cl. 327/116

(57) ABSTRACT

The present invention relates to a circuit providing frequency-doubling function. More particularly, the present invention relates to a frequency doubler circuit comprising dual Gilbert mixers in replace with the single mixer scheme in the conventional direct conversion transceiver circuit. CMOS technology is preferred in order to lower size and power consumption of the specific IC. With a balanced output load, either is resistor-capacitor (RC) load, resistor-inductor (RL) load, or a combination of the three (RLC), symmetrical output waveforms are obtained thereby. Notice that two quadrature inputs and their inverse-phase signals are provided to the purposed dual Gilbert mixer circuit, and two outputs in inverse-phase are obtained accordingly as meditated in this invention.

### BACKGROUND OF THE INVENTION

1. Field of Invention

The present invention relates to generating frequency according to local oscillating frequency used in wireless direct conversion transceiver. More particularly, the present invention relates to a frequency doubler in order to avoid interference between Low Noise Amplifier (LNA) and voltage controlled oscillator (VCO) or power amplifier (PA) and VCO in wireless direct conversion transceiver where VCO is made half of the frequency of local oscillator.

2. Description of Related Art

A wireless direct conversion transceiver is a candidate for realizing low cost and small size terminals using BiCMOS fabrication technology. The circuit comprising a frequency doubler scheme is effective for reducing serious interference between Power Amplifier (PA) and Voltage Controlled Oscillator (VCO) by making the VCO frequency different from that of PA. This practical solution to the problems is to use a frequency DouBLeR (DBLR) in a Local Oscillator (LO) signal path. However, the mixer circuit in the frequency-doubler scheme generates asymmetrical waveforms for the doubled frequency 2f_{LO}. Thus, a dual-mixer circuit is introduced in this invention to eliminate asymmetry problems, and is as well implemented in CMOS technology in order to lower power consumption.

### SUMMARY OF THE INVENTION

As embodied and broadly described herein, the invention provides a frequency doubler circuit comprising dual Gilbert mixers in replace with the single mixer scheme in the conventional direct conversion transceiver circuit. CMOS technology is preferred in order to lower size and power consumption of the specific IC. With a balanced output load, which is either resistor-capacitor (RC) load, resistor-inductor (RL) load, or a combination of the three (RLC), symmetrical output waveforms are obtained thereby. Notice that two quadrature inputs and their inverse-phase signals are provided to the purposed dual Gilbert mixer circuit, and two outputs in inverse-phase are obtained accordingly as meditated in this invention.

These and other objects, features and advantages of the present invention will become apparent from the following detailed description of illustrative embodiments thereof, which is to be read in connection with the accompanying drawings.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic circuit providing frequency-doubling function in prior art.

FIG. 2 is a schematic circuit comprising dual Gilbert mixer blocks and RC (resistor-capacitor) load according to one preferred embodiment of this invention.

FIG. 3 is a schematic circuit demonstrating a Gilbert mixer comprising CMOS transistors and a current source according to one preferred embodiment of this invention.

FIG. 4 is a schematic circuit demonstrating a Gilbert mixer comprising CMOS transistors (without tail current source, as opposed to FIG. 3) according to one preferred embodiment of this invention.

FIG. 5 is a diagram of the input and output waveforms of the frequency doubler according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

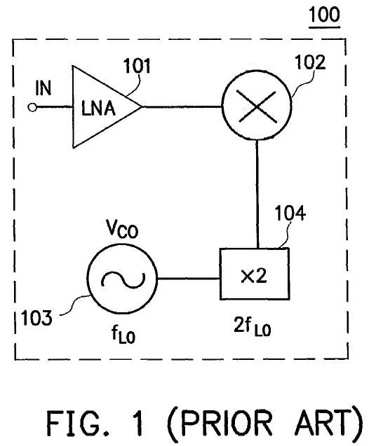

In realizing a direct conversion transceiver, a frequency doubler is a key component to avoid interference between Power Amplifier (PA) and Voltage Controlled Oscillator (VCO). A transceiver circuit including a frequency doubler is briefly shown in FIG. 1. Referring to FIG. 1, a frequency doubler circuit 100 is illustrated herein. The input signal is fed into Low Noise Amplifier (LNA) 101, and is mixed with a doubled oscillating frequency at mixer 102. The oscillating frequency is generated at a VCO oscillator 103 and is doubled at a frequency doubler 104 so as to implement mixing scheme. However, the input impedance of the conventional frequency doubler is not designed to be balanced, thus poor sinusoidal output waveforms are generated so that are not being symmetrical for further usage.

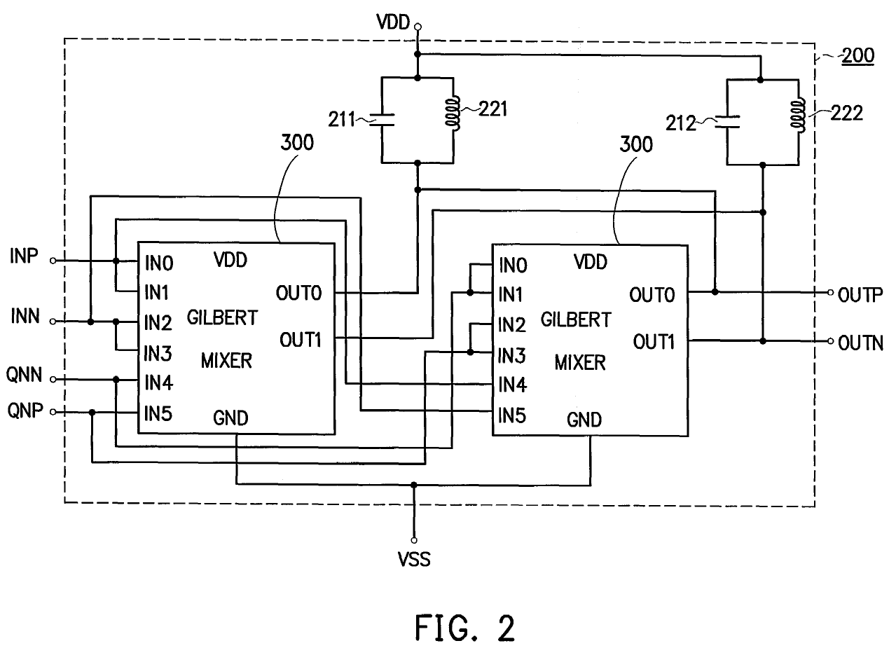

The concept of tuning the waveforms in this present invention is to balance out input impedance of the internal circuit of the frequency doubler, as well as to choose output load carefully in order to obtain the symmetry of output waveforms. The first scheme provided by this present invention is to use dual identical circuit in the frequency doubler, i.e. to use two identical Gilbert mixers, as shown in FIG. 2. Referring to FIG. 2, the frequency doubler circuit 200 comprises dual Gilbert mixer 300 and output load consisting capacitors 211 and 212, and inductors 221 and 222. Considering input signals firstly, a LO frequency (INP) and its inverse (INN), and a 90° shifted frequency (QNP), i.e. by quadrature, and its inverse (QNN), are provided for the frequency doubler circuit in this preferred embodiment. Further considering connections of the elements in this circuit. A block of the Gilbert mixer 300 in this present invention comprises six input terminals and two output terminals, which are IN0, IN1, . . . , IN5 and OUT0 to OUT1. Notice that IN0 and IN1 are connected in a pair, and IN2 and IN3 are connected in a pair for this application in this preferred embodiment. It is obvious that the two Gilbert mixers and the two loads in this embodied circuit are symmetrically constructed, thus the connection scheme shown in FIG. 2 is not the only topology. In the exemplary connection in this preferred embodiment, input signal INP feeds IN0 and IN1 of the first Gilbert mixer and IN4 of the second Gilbert mixer, while input signal INN feeds the IN2 and IN3 of the first Gilbert mixer and IN5 of the second Gilbert mixer. Meanwhile, QNP feeds IN5 of the first Gilbert mixer and IN2 and IN3 of the second Gilbert mixer, as well as QNN feeds IN4 of the first Gilbert mixer and IN0 and IN1 of the second Gilbert mixer. The first output terminal OUT0 of each Gilbert mixer is connected to the second terminals of capacitor 211 and inductor 221, while the second output terminal OUT1 of each Gilbert mixer is connected to the second terminal of capacitor 212 and inductor 222. These output terminals are then marked OUTP and OUTN of the frequency doubler circuit in FIG. 2. Notice that each of the first and second loads is implemented in parallel capacitor-inductor arrangement in this preferred embodiment, as well as implemented with at least one of resistor, capacitor and inductor.

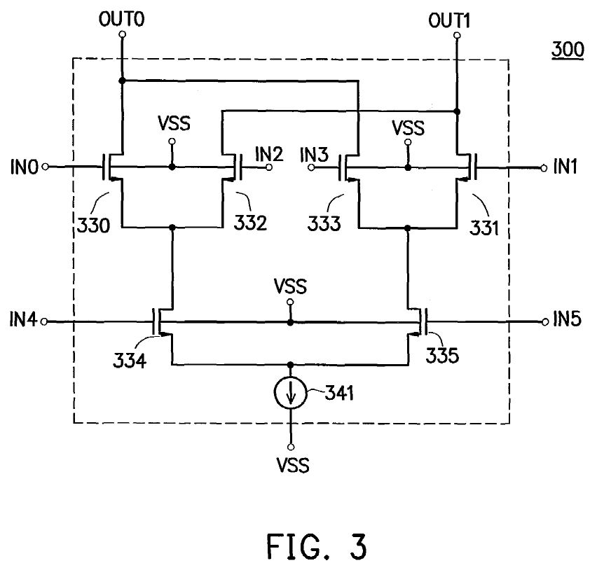

Referring to FIG. 3 for understanding internal construction of the Gilbert mixer 300 in FIG. 2, six NMOS transistors 330 to 335 and a current source 341 build the circuit therein. The gates of the transistors 330 to 335 correspond to the input terminals IN0 to IN5 in block diagram in FIG. 2, whereas OUT0 and OUT1 are actually coupled to the drains of transistors 330, 333 and the drains of transistors 331, 332 respectively. For the remaining connections, the sources of transistors 330 and 332 are coupled to the drain of transistor 334, while the sources of transistors 331 and 333 are coupled to the drain of transistor 335. Lastly, the positive terminal of current source 341 couples to the sources of transistor 334 and 335, and its negative terminal couples to VSS. Notice that providing the transistor sizes are carefully chosen, the input impedance seen from the top level of the frequency doubler is balanced out for each of the input terminals.

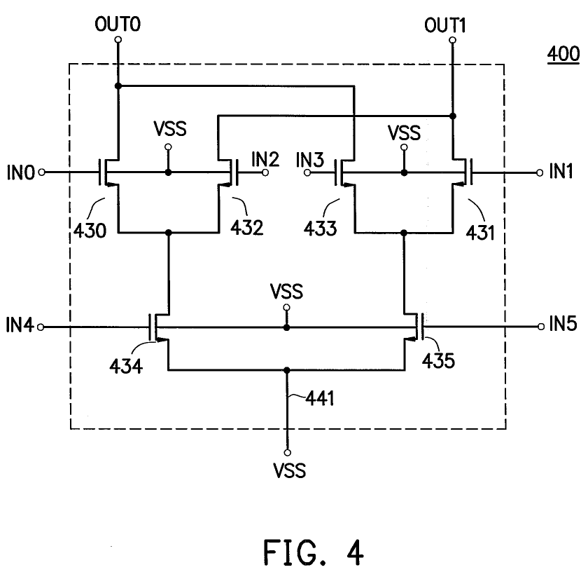

Referring to FIG. 4, another preferred embodiment of the internal construction of the Gilbert mixer is illustrated as 400 in replace with 300, where six NMOS transistors 430 to 435 build the circuit therein. The gates of the transistors 430 to 435 correspond to the input terminals IN0 to IN5 in bock diagram in FIG. 2, whereas OUT0 and OUT1 are actually coupled to the drains of transistors 430, 433 and the drains of transistors 431, 432 respectively. For the remaining connections, the sources of transistors 430 and 432 are coupled to the drain of transistor 434, while the sources of transistors 431 and 433 are coupled to the drain of transistor 435. Lastly, the positive terminal of current source 441 couples to the sources of transistor 434 and 435, and its negative terminal couples to VSS. Notice that providing the transistor sizes are carefully chosen, the input impedance seen from the top level of the frequency doubler is balanced out for each of the input terminals.

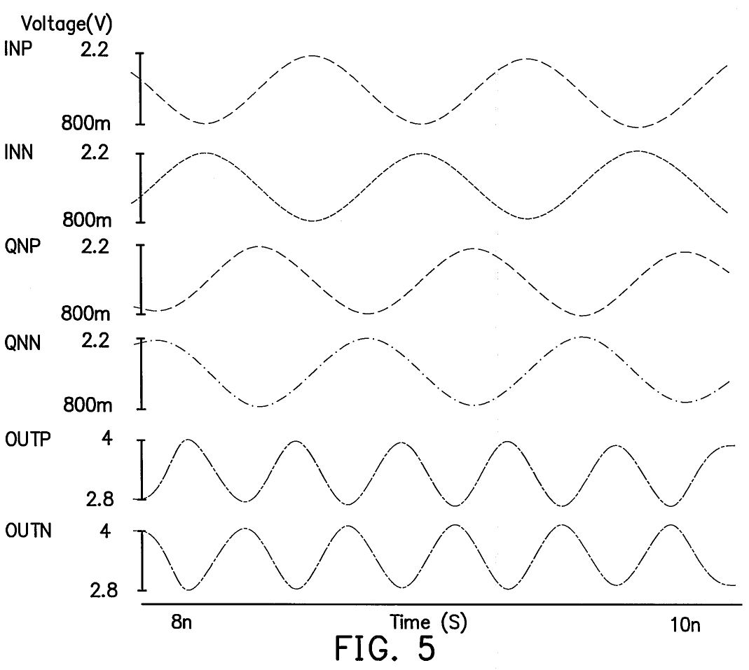

Referring to FIG. 5, the input and output waveforms are shown in the diagram. As demonstrated, INP, INN are in inverse-phase manner, QNP and QNN are in inverse-phase manner, QNP and INP are differed by 90° in phase, that is in quadrature-phase. As a result, OUTP and OUTN are the output waveforms in inverse-phase to each other thus demonstrate doubling frequency. Notice that symmetrical waveforms are obtained as designed.

Ultimately, NMOS transistors and CMOS semiconductor technology are applied in this preferred embodiment in the present invention in order to achieve small size and to lower power consumption. Yet other available semiconductor technologies also apply, BiCMOS technology for example, as long as the spirit and scope of this present invention are satisfied.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A frequency doubler circuit comprising:
a first Gilbert mixer having at least four input terminals and at least two output terminals;
a second Gilbert mixer having at least four input terminals and at least two output terminals,
wherein a first input terminal of the first Gilbert mixer and a third input terminal of the second Gilbert mixer are coupled together for receiving an in-phase input signal,
wherein a second input terminal of the first Gilbert mixer and a fourth input terminal of the second Gilbert mixer are coupled together for receiving inverse of the in-phase input signal,
wherein a third input terminal of the first Gilbert mixer and a first input terminal of the second Gilbert mixer are connected for receiving inverse of a quadrature-phase input signal, and
wherein a fourth input terminal of the first Gilbert mixer and a second input terminal of the second Gilbert mixer are connected for receiving the quadrature-phase input signal;
a first output terminal of the first Gilbert mixer and a first output terminal of the second Gilbert mixer are connected to a first node;
a second output terminal of the first Gilbert mixer and a second terminal of the second Gilbert mixer are connected to second node;
a first load interposed between a power supply terminal and the first node; and
a second load interposed between the power supply terminal and the second node.

2. The frequency doubler circuit as recited in claim 1, wherein either of the first Gilbert mixer or the second Gilbert mixer, for mixing at least two local oscillating signals that are differentiated by quadrature phase, comprising:
a first differential pair of transistors coupled together at a first node for receiving a first current, wherein the first differential pair of transistors is fed with an inverse-phase differential signal;
a second differential pair of transistors coupled together at a second node for receiving a second current, wherein the second differential pair of transistors is fed with the inverse-phase differential signal;
a third differential pair of transistors having a first terminal coupled to the first node to provide the first current thereto, a second terminal coupled to a quadrature terminal for receiving a quadrature signal, a third node for the third differential pair of transistors coupled together for receiving a third current, wherein the differential pair of transistors is fed with an inverse-phase differential signal; and
a current source connected directly to the third node to provide the third current thereto.

3. The frequency doubler circuit as recited in claim 1, wherein either the first Gilbert mixer or the second Gilbert mixer, for mixing at least two local oscillating signals that is differentiated by quadrature, at least comprising:
a first differential pair of transistors coupled together at a first node for receiving a first current, wherein the first differential pair of transistors is fed with an inverse-phase differential signal;
a second differential pair of transistors coupled together at a second node for receiving a second current, wherein the second differential pair of transistors is fed with the inverse-phase differential signal;
a third differential pair of transistors having a first terminal coupled to the first node to provide the first current thereto, a second terminal coupled to a quadrature terminal for receiving a quadrature signal, a third node for the third differential pair of transistors coupled together for receiving a third current, wherein the differential pair of transistors is fed with an inverse-phase differential signal; and
a power supply terminal connected directly to the third node.

4. The frequency doubler circuit as recited in claim 1, wherein the first load or the second load comprise at least one of resistance, inductance, and capacitance, and the first load and the second load are chosen so as to obtain symmetrical output waveforms.

5. The frequency doubler as recited in claim 2, wherein the transistors and the current source are implemented with NMOS transistors, integrated in a transceiver circuit and fabricated in CMOS semiconductor technology, wherein the current source comprises a plurality of transistors.

6. The frequency doubler as recited in claim 3, wherein the transistors and the current source are integrated in a transceiver circuit and fabricated in other available semiconductor technologies, for example BiCMOS technology, wherein the current source comprises a plurality of transistors.

7. The frequency doubler as recited in claim 3, wherein the transistors are implemented with NMOS transistors, integrated in a transceiver circuit and fabricated in CMOS semiconductor technology, wherein the current source comprises a plurality of transistors.

8. The frequency doubler as recited in claim 3, wherein the transistors are integrated in a transceiver circuit and fabricated in other available semiconductor technologies, for example BiCMOS technology, wherein the current source comprises a plurality of transistors.
